(19) United States
(12) Patent Application Publication
(10) Pub. No.: US 2026/0123034 A1
(43) Pub. Date: Apr. 30, 2026

(54) SEMICONDUCTOR DEVICES AND METHODS FOR FORMING THE SAME

(71) Applicant: Yangtze Memory Technologies Co., Ltd., Wuhan (CN)

(72) Inventors: Danyang Wei, Wuhan (CN); Liang Chen, Wuhan (CN); Yaqin Liu, Wuhan (CN); Wei Liu, Wuhan (CN); Xin Wang, Wuhan (CN); Wenshan Xu, Wuhan (CN); Ning Jiang, Wuhan (CN)

(21) Appl. No.: 19/011,429

(22) Filed: Jan. 6, 2025

Related U.S. Application Data
(63) Continuation of application No. PCT/CN2024/128881, filed on Oct. 31, 2024.

(51) Int. Cl. H10D 84/83; H01L 21/762; H10D 84/01

(52) U.S. Cl. CPC H10D 84/83; H10D 84/0126; H10W 10/014; H10W 10/17

(57) ABSTRACT

A semiconductor device and a corresponding fabricating method are provided. The semiconductor device includes a substrate and an active area in the substrate. The semiconductor device further includes at least one isolation structure positioned between two adjacent transistors. Each isolation structure includes a conductive core, and a dielectric layer surrounding the conductive core and positioned between the conductive core and an adjacent transistor.

### CROSS-REFERENCE TO RELATED APPLICATIONS

This application is a continuation of International Application No. PCT/CN2024/128881, filed on Oct. 31, 2024, which is hereby incorporated by reference in its entirety.

### BACKGROUND

The present disclosure relates to semiconductor devices and methods for forming thereof.

Planar memory cells are scaled to smaller sizes by improving process technology, circuit design, programming algorithm, and fabrication process. However, as feature sizes of the memory cells approach a lower limit, planar process and fabrication techniques become challenging and costly.

### SUMMARY

In one aspect, a semiconductor device including a substrate and an active area in the substrate is provided. The semiconductor device further includes at least one isolation structure positioned between two adjacent transistors. Each isolation structure of the at least one isolation structure includes a conductive core and a dielectric layer surrounding the conductive core and positioned between the conductive core and an adjacent transistor.

In some implementations, the conductive core has a grid pattern in a lateral plane, and the dielectric layer are split into a plurality of units by the conductive core in the lateral plane.

In some implementations, each unit of the dielectric layer surrounds and isolates at least one transistor in the lateral plane.

In some implementations, along a vertical direction, a first distance between a bottom of the conductive core and a bottom of the substrate is smaller than a second distance between a bottom of the active area a bottom of the active area and the bottom of the substrate.

In some implementations, along the vertical direction, the conductive core includes a first portion in the substrate and a second portion extended above the substrate and coupled to a conductive layer.

In some implementations, the conductive core includes a protrusion on a joint portion between the first portion and the second portion on a cross-section along the vertical direction.

In some implementations, a third distance between the bottom of the conductive core and a top of the active area ranges from 0.2 um to 0.8 um.

In some implementations, a fourth distance is a minimal distance between two adjacent transistors, and a ratio of the third distance to a fourth distance ranges from 1:1.5 to 1:0.125.

In some implementations, the dielectric layer includes a different material from isolation materials covering the substrate of the semiconductor device.

In some implementations, a material of the conductive core includes at least one of polysilicon, metal, or conductive composite.

In another aspect, a method for fabricating a semiconductor device is provided. The method includes: forming a substrate with an active area; forming at least one isolation structure in the active area; and forming a plurality of transistors isolated by the at least one isolation structure. Each isolation structure of the at least one isolation structure includes a conductive core and a dielectric layer surrounding the conductive core and positioned between the conductive core and an adjacent transistor.

In some implementations, the conductive core has a grid-patterned structure in a lateral plane, and the dielectric layer are split into a plurality of units by the grid-patterned structure of the conductive core in the lateral plane.

In some implementations, each unit of the dielectric layer surrounds and isolates at least one transistor in the lateral plane.

In some implementations, forming the at least one isolation structure includes: forming at least one isolating trench; forming a first dielectric layer covering a surface of the at least one isolating trench; and filling the at least one isolating trench with a dielectric core having a different material from the first dielectric layer.

In some implementations, a depth of the at least one isolating trench is greater than a depth of the active area.

In some implementations, a depth of the first dielectric layer is greater than a depth of the active area.

In some implementations, forming the isolation structure further includes polishing the first dielectric layer by chemical mechanical planarization (CMP) to expose a top surface of the active area.

In some implementations, forming the plurality of transistors isolated by the at least one isolation structure includes forming a plurality of pairs of source/drain regions in the active area and forming gate structures on the top surface of the active area corresponding to the plurality of pairs of source/drain regions.

In some implementations, the method further includes forming an interlayer dielectric layer covering the substrate and the plurality of transistors. The interlayer dielectric layer and the first dielectric layer have a same material.

In some implementations, forming the isolation structure further includes forming a trench throughout the interlayer dielectric layer and the dielectric core to expose the first dielectric layer.

In some implementations, forming the isolation structure further includes forming a second dielectric layer covering the isolation trench before forming the first dielectric layer, and the second dielectric layer and the first dielectric layer have different materials.

In some implementations, the method further includes forming a plurality of holes throughout the interlayer dielectric layer to expose source/drain regions and gate structures of the transistors. The plurality of holes are formed in a same formation process of the trench.

In some implementations, forming the isolation structure further includes forming the conductive core in the trench by depositing a conductive material in the trench.

In some implementations, the method further includes forming a plurality of interconnectors in the plurality of holes by depositing the conductive material in the plurality of holes. The plurality of interconnectors are formed in a same formation process as the conductive core.

In some implementations, the conductive material includes at least one of polysilicon, metal, or conductive composite.

In some implementations, the method further includes coupling the conductive core to a conductive layer formed on the interlayer dielectric layer.

In yet another aspect, a method for fabricating a semiconductor device is provided. The method includes: forming a substrate with an active area; and forming at least one isolation structure in the active area and a plurality of transistors isolated by the at least one isolation structure. Each isolation structure of the at least one isolation structure includes a conductive core and a dielectric layer surrounding the conductive core and positioned between the conductive core and an adjacent transistor. Gates of the plurality of transistors and the conductive core have a same material.

In some implementations, forming at least one isolation structure in the active area and the plurality of transistors includes forming at least one isolating trench in the substrate and forming the dielectric layer covering a surface of the isolating trench.

In some implementations, forming at least one isolation structure in the active area and the plurality of transistors includes: forming a plurality of gate dielectrics of the plurality of transistors on the active area of the substrate.

In some implementations, forming at least one isolation structure in the active area and the plurality of transistors includes forming a sacrifice layer covering the substrate. A material of the sacrifice layer is different from the substrate and forming a plurality of openings on the sacrifice layer to expose the plurality of gate dielectrics and the isolating trench.

In some implementations, forming at least one isolation structure in the active area and the plurality of transistors includes forming the conductive core in the isolating trench; forming a plurality of conductive gates on the plurality of gate dielectrics; and forming a plurality of pairs of source/drain regions in the active area corresponding to the plurality of conductive gates. The conductive core and the conductive gates are formed in a same formation process by depositing conductive materials via the plurality of openings.

In some implementations, forming at least one isolation structure in the active area and the plurality of transistors includes: forming an interlayer dielectric layer covering the substrate and the transistors; forming a plurality of holes throughout the interlayer dielectric layer to expose the conductive core, the source/drain regions, and gate structures; and forming a plurality of interconnectors in the plurality of holes.

In some implementations, the method further includes coupling the conductive core to a conductive layer formed on the interlayer dielectric layer.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1A illustrates a top view of a semiconductor device, according to some aspects of the present disclosure.

FIG. 1B illustrates a schematic view of a cross-section along AA′ direction of the semiconductor device in FIG. 1A.

FIG. 2A illustrates a top view of a semiconductor device, according to some aspects of the present disclosure.

FIG. 2B illustrates a schematic view of a cross-section along AA′ direction of the semiconductor device in FIG. 2A.

FIG. 3A illustrates a top view of a semiconductor device, according to some aspects of the present disclosure.

FIG. 3B illustrates a schematic view of a cross-section along AA′ direction of the semiconductor device in FIG. 2A.

FIG. 4A illustrates a top view of a semiconductor device, according to some aspects of the present disclosure.

FIG. 4B illustrates a top view of a semiconductor device, according to some aspects of the present disclosure.

FIG. 5 illustrates a flowchart of a method for forming a semiconductor device, according to some aspects of the present disclosure.

FIG. 6A-6J illustrate a fabrication process for forming a semiconductor device, according to some aspects of the present disclosure.

FIG. 7 illustrates a flowchart of a method for forming a semiconductor device, according to some aspects of the present disclosure.

FIG. 8A-8J illustrate a fabrication process for forming a semiconductor device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

High-voltage memory cells play a crucial role in integrated circuits tailored for high-voltage and high-power applications. These cells typically operate at voltage levels of 18 volts or higher. To mitigate the risk of punch-through, it is essential to implement isolation structures between adjacent high-voltage memory cells, as well as between high-voltage and low-voltage memory cells. Typically, these isolation structures should be at least three times wider than those used between low-voltage memory cells to effectively prevent punch-through resulting from elevated voltage levels. Consequently, as semiconductor device sizes decrease, the width of these isolation structures cannot be proportionately reduced. This constraint leads to an increasing proportion of the overall area of the memory device being occupied by isolation structures, thereby posing significant challenges to efforts aimed at reducing costs.

To address the aforementioned issues, the present disclosure introduces a solution whereby a conductive core is incorporated into the isolation structures between adjacent high voltage memory cells. This conductive core may be connected to a negative voltage or grounded, preventing charge accumulation between adjacent memory cells and thereby mitigating the risk of punch-through. Because the charge shielding capability of the conductive core is independent of its thickness, the width of the isolation structure containing the conductive core can be significantly narrower than that of traditional isolation structures. As a result, the overall area of the isolation structures in the high-voltage memory device can be substantially reduced, leading to cost savings. Moreover, the integration of the conductive core into the fabrication of the isolation structures can be fully accomplished within existing manufacturing processes for memory devices, eliminating the need for additional processes or masks, and requiring no extra costs.

In some implementations, the high-voltage transistors described herein encompass a variety of types, including Metal-Oxide-Semiconductor Field-Effect Transistors (MOSFETs), Junction Field-Effect Transistors (JFETs), Heterojunction Bipolar Transistors (HBTs), Silicon Controlled Rectifiers (SCRs), Tunnel Field-Effect Transistors (TFETs), and Insulated-Gate Bipolar Transistors (IGBTs), among others. For instance, high-voltage MOSFETs are specifically engineered to operate at voltage levels exceeding 30 volts, characterized by low on-resistance and rapid switching speeds. These attributes significantly reduce power loss while enhancing the operational efficiency of memory devices. Moreover, the planar architecture of MOSFETs facilitates their seamless integration into densely packed memory arrays.

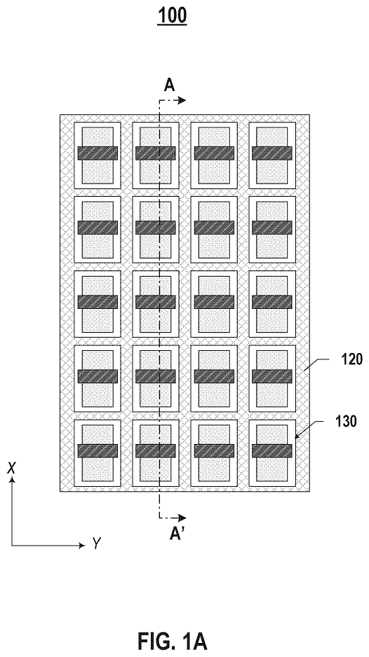

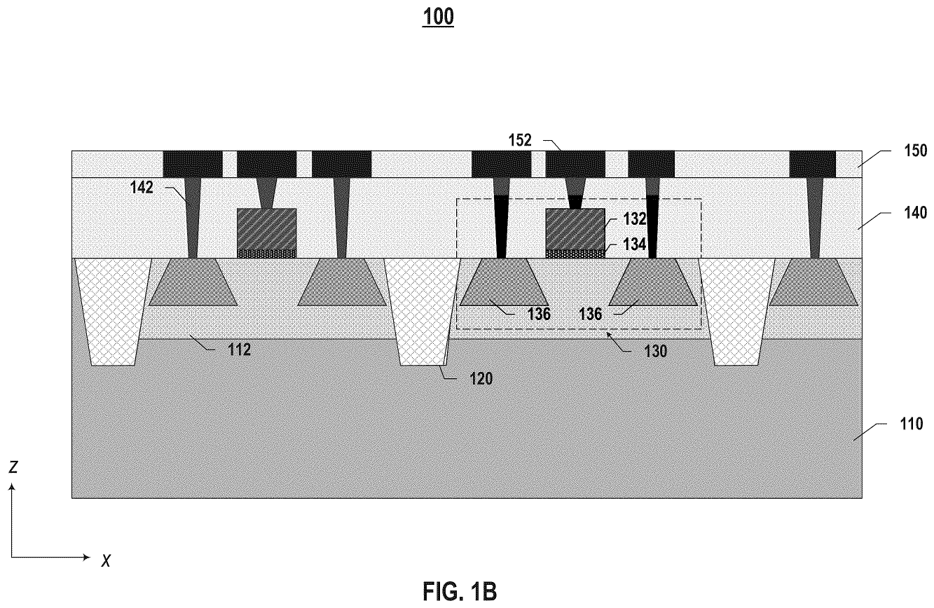

FIG. 1A illustrates a top view of a semiconductor device 100, according to some aspects of the present disclosure. FIG. 1B illustrates a schematic view of a cross-section along AA′ direction of the semiconductor device 100 in FIG. 1A. Semiconductor device 100 represents an example of a high voltage memory device including planer transistors 130 formed on a substrate 110. Trench isolations (e.g., shallow trench isolations (STIs)) and doped regions (e.g., wells, sources, and drains of transistors 130) can be formed on or in substrate 110. Substrate 110 can include silicon (e.g., single crystalline silicon, c-Si), silicon germanium (SiGe), gallium arsenide (GaAs), germanium (Ge), silicon-on-insulator (SOI), or any other suitable materials. In some implementations, transistor 130 includes an active area 112 extending laterally (in the x-y plane) and a gate structure formed thereon. The gate structure can include a gate dielectric 134 and a gate electrode 132 coupled with gate dielectric 134. In some implementations, gate dielectric 134 is vertically between gate electrode 132 and active area 112 in the z-direction, and the source/drain regions 136 are disposed in active area 112 symmetrically about the gate structure.

In some implementations, two adjacent transistor 130 are isolated by a trench isolation 120 extending in the vertical direction (the z-direction). A bottom of trench isolation 120 extends beyond a bottom of active area 112 to prevent being punched through. In some implementations, trench isolation 120 has a grip-patterned structure in the lateral plane (in the x-y plane). The plurality of transistors 130 are isolated from each other by the grip-patterned trench isolation 120.

Semiconductor device 100 further includes an interconnect layer coupled with transistors 130 through a plurality of connectors 142. The interconnect layer is formed on an ILD layer 140 to transfer electrical signals. As used herein, the term “interconnects” can broadly include any suitable types of interconnects, such as middle-end-of-line (MEOL) interconnects and back-end-of-line (BEOL) interconnects. The interconnect layer can further include one or more interlayer dielectric (ILD) layers (also known as “intermetal dielectric (IMD) layers”) in which the interconnect lines and via contacts can form. That is, the interconnect layer can include interconnect lines and via contacts in multiple ILD layers, such as ILD layer 140 and ILD layer 150. The interconnects in the interconnect layer can include conductive materials including, but not limited to, W, Co, Cu, Al, doped silicon, silicide, or any combination thereof. The ILD layers can be formed with dielectric materials including, but not limited to, silicon oxide, silicon nitride, silicon oxynitride, low-k dielectrics, or any combination thereof.

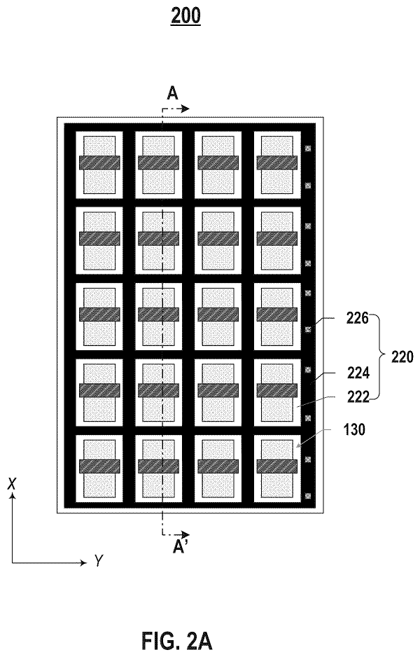

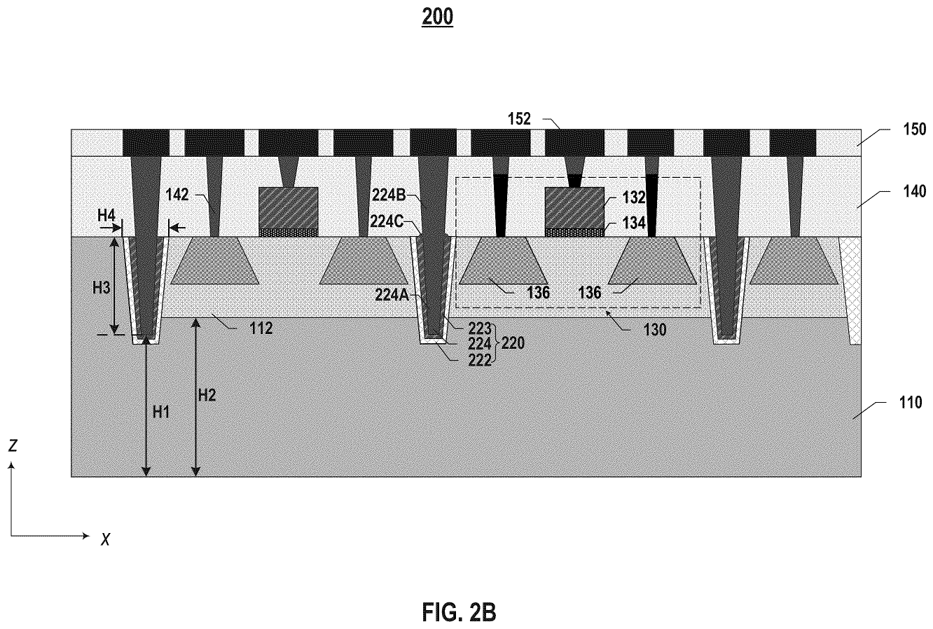

In some implementations, to proportionately reduce the size of the trench isolation 120, a semiconductor device 200 is provided. FIG. 2A illustrates a top view of a semiconductor device 200, according to some aspects of the present disclosure. FIG. 2B illustrates a schematic view of a cross-section along AA′ direction of the semiconductor device 200 in FIG. 2A. Semiconductor device 200 can be a high voltage memory device including planer transistors 130 formed on a substrate 110. Substrate 110 can include silicon (e.g., single crystalline silicon, c-Si), silicon germanium (SiGe), gallium arsenide (GaAs), germanium (Ge), silicon-on-insulator (SOI), or any other suitable materials. In some implementations, transistor 130 includes an active area 112 extending laterally (in the x-y plane) and a gate structure formed thereon. The gate structure can include a gate dielectric 134 and a gate electrode 132 coupled with gate dielectric 134. In some implementations, gate dielectric 134 is vertically between gate electrode 132 and active area 112 in the z-direction, and the source/drain regions 136 are disposed in active area 112 symmetrically about the gate structure.

As shown in FIGS. 2A and 2B, semiconductor device 200 further includes at least one isolation structure 220 positioned between two adjacent transistors 130. The plurality of transistors 130 are isolated from each other by the isolation structure 220. Each isolation structure 220 includes a conductive core 224 and a first dielectric layer 222 surrounding conductive core 224 and positioned between conductive core 224 and an adjacent transistor 130. Conductive core 224 includes conductive materials including, but not limited to, W, Co, Cu, Al, TiN, TaN, polysilicon, silicide, or any combination thereof. Isolation structure 220 includes dielectric materials such as silicon oxide or silicon nitride.

Referring to FIG. 2A and FIG. 2B, the conductive core 224 can be connected to a negative voltage or grounded, functioning as a metal shield to neutralize or discharge the charge accumulated within and around the isolation structure 220. This arrangement effectively prevents punching-through, as the charges accumulated within and surround isolation structure 220 are unable to reach the voltage necessary for punch-through to occur. Additionally, as illustrated in FIG. 1B and FIG. 2B, the capacity of isolation structure 220 to prevent punching-through is not dependent on the width of the isolation structure 220; therefore, the width of isolation structure 220 can be significantly reduced in comparison to the width of trench isolation 120 in semiconductor device 100. Consequently, this reduction allows for a decrease in the area occupied by the high-voltage transistors.

In some implementations, along the vertical direction (in the z-direction), a first distance H1 between a bottom of conductive core 224 and a bottom of substrate 110 is smaller than a second distance H2 between a bottom of active area 112 and the bottom of substrate 110. That is, a bottom of conductive core 224 extends beyond the bottom of active area 112 to minimize the risk of punch through between two adjacent transistors 130. Referring to FIG. 2B, a third distance H3 is a distance between the bottom of conductive core 224 and a top of active area 112, and a fourth distance H4 is a minimal distance between two adjacent transistors 130. In some implementations, third distance H3 ranges from 0.2 um to 0.8 um, and a ratio of third distance H3 to fourth distance H4 ranges from 1:1.5 to 1:0.125. For example, in some implementations, the ratio is 1:0.5, whereby third distance H3 is twice of fourth distance H4. In other implementations, the ratio is 1:0.25, whereby third distance H3 is four times of the fourth distance H4. In other implementations, the ratio is 1:0.125, whereby third distance H3 is eight times of the fourth distance H4. With the introduction of conductive core 224, third distance H3 is becoming increasingly smaller compared to fourth distance H4.

In some implementations, isolation structure 220 further includes a second dielectric layer 223 located between conductive core 224 and first dielectric layer 222. Second dielectric layer 223 includes dielectric materials such as silicon oxide or silicon nitride. In some implementations, second dielectric layer 223 has a different material from first dielectric layer 222, and at least one of first dielectric layer 222 or second dielectric layer 223 has a different material from ILD layer 140. The dielectric stack including first dielectric layer 222 and second dielectric layer 223 ensures that conductive core 224 is fully surrounded by dielectric materials, preventing any contact with the active areas 112 of the adjacent transistor 130.

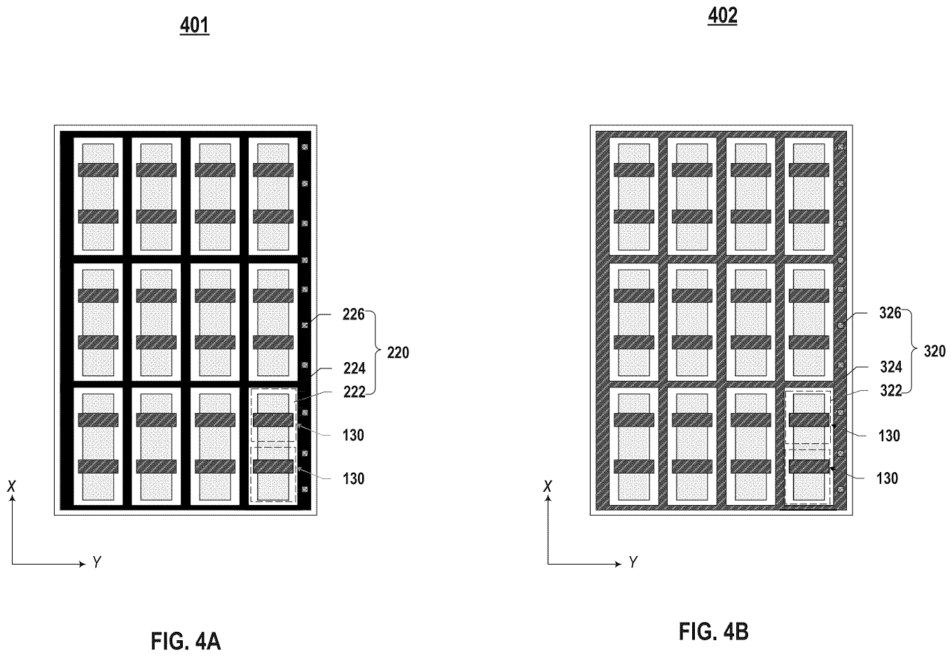

In some implementations, as illustrated in FIG. 2A, the conductive core 224 features a grip-patterned structure in the lateral plane (the x-y plane). First dielectric layer 222 is divided into multiple units by the grid-patterned configuration of conductive core 224 in the lateral plane, with each unit of the first dielectric layer 222 surrounding and isolating at least one transistor 130 within that plane. In some implementations, at least two transistors 130 are surrounded by each unit of first dielectric layer 322, as shown in semiconductor device 401 in FIG. 4A. In some implementations, the number of transistors 130 surrounded and isolated by each unit of first dielectric layer 222 varies. For example, part unit of first dielectric layer 222 surrounds and isolates one transistor 130 while other units surround and isolate two, three, or four transistors 130. The number of transistors 130 that are surrounded and isolated by each unit of first dielectric layer 222 is determined by the design and the structure of semiconductor device 401 and should not be read as a limit of the present disclosure. Furthermore, conductive core 224 includes multiple contacts 226 situated at its edge, facilitating a connection between conductive core 224 and a negative voltage or ground. The number and locations of contacts 226 can be arranged based on the area and shape of the semiconductor device 100 in consideration of its fabrication process. It should be noted that the shape of conductive core 224 is illustrative and should not be read as limits of the present disclosure. For example, conductive core 224 may be strips parallel to each other in other implementations.

In some implementations, referring to FIG. 2B, along the vertical direction (the z-direction), conductive core 224 includes a first portion 224A located in substrate 110 and a second portion 224B extended above substrate 110 and through ILD layer 140 to couple with contacts 152 of the interconnect layer. In some implementations, conductive core 224 further includes a protrusion 224C on a joint portion between first portion 224A and second portion 224B on a cross-section along the vertical direction. That is, protrusion 224C is formed at an interface between substrate 110 and ILD layer 140.

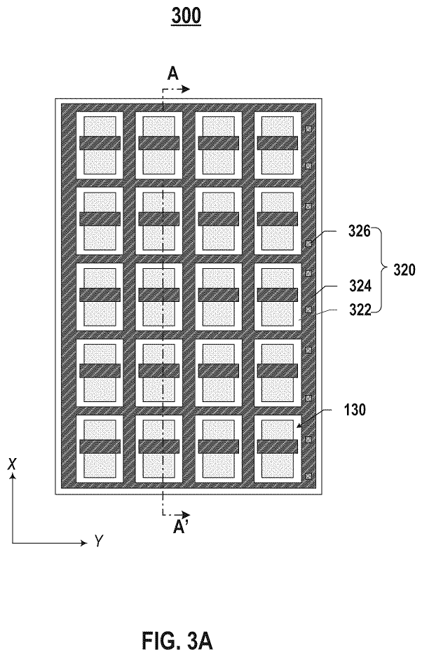

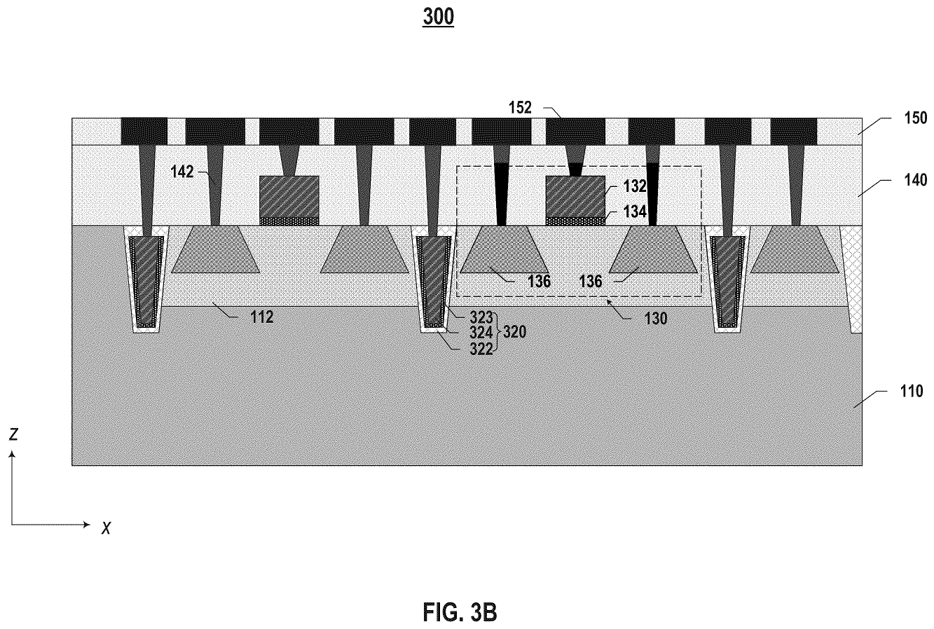

In some implementations, to proportionately reduce the size of the trench isolation, a semiconductor device 300 is provided. FIG. 3A illustrates a top view of a semiconductor device 300, according to some aspects of the present disclosure. FIG. 3B illustrates a schematic view of a cross-section along AA′ direction of the semiconductor device 300 in FIG. 3A. Semiconductor device 300 can be a high voltage memory device including planer transistors 130 formed on a substrate 110. In some implementations, transistor 130 includes an active area 112 extending laterally (in the x-y plane) and a gate structure formed thereon. The gate structure can include a gate dielectric 134 and a gate electrode 132 coupled with gate dielectric 134. In some implementations, gate dielectric 134 is vertically between gate electrode 132 and active area 112 in the z-direction, and the source/drain regions 136 are disposed in active area 112 symmetrically about the gate structure.

In some implementations, as shown in FIGS. 3A and 3B, semiconductor device 300 includes at least one isolation structure 320 positioned between two adjacent transistors 130. The plurality of transistors 130 are isolated from each other by the isolation structure 220. Each isolation structure 320 includes a conductive core 324 and a first dielectric layer 322 surrounding conductive core 324 and positioned between conductive core 324 and an adjacent transistor 130. Conductive core 324 can be made of conductive materials including, but not limited to, W, Co, Cu, Al, TiN, TaN, polysilicon, silicide, or any combination thereof.

In some implementations, isolation structure 320 further includes a second dielectric layer 323 located between conductive core 324 and first dielectric layer 322. Conductive core 324 and second dielectric layer 323 are formed in the same fabrication processes as the gate structure. As a result, conductive core 324 has a same material as gate electrode 132. For example, both conductive core 324 and gate electrode 132 are made of polysilicon. In some implementations, second dielectric layer 323 has the same material as gate dielectric 134, such as oxide, silicon nitride, or high-k dielectrics including, but not limited to, Al₂O₃, HfO₂, Ta₂O₅, ZrO₂, TiO₂, or any combination thereof. Consequently, isolation structure 320 shares the same structure and materials as the gate structure, as depicted in FIG. 3B. In this implementation, the formation of conductive core 324 can be fully integrated into the existing fabrication process for the gate structure, eliminating the need for any additional fabrication steps. Thus, the fabrication processes for semiconductor device 100 and semiconductor device 300 are identical, except that the masks used in certain etching steps differ in shape. As a result, conductive core 324 can be incorporated into semiconductor device 300 without incurring any additional costs.

In some implementations, a depth of isolation structure 320 is the same as a height of the gate structure because they are formed in the same fabrication processes. The depth of isolation structure 320 is determined by the height of the gate structure in semiconductor device 300. Therefore, in some implementations, a top surface of isolation structure 320 is beneath the top surface of active area 112, as shown in FIG. 3B. in some implementations, the top surface of isolation structure 320 can be equal to or go beyond the top surface of active area 112, as shown in FIG. 3B. Referring to FIG. 3A and FIG. 3B, as described above, the conductive core 324 can be connected to a negative voltage or grounded, functioning as a metal shield to neutralize or discharge the charge accumulated within and around the isolation structure 320.

In some implementations, as illustrated in FIG. 3A, the conductive core 324 features a grip-patterned structure in the lateral plane (the x-y plane). First dielectric layer 322 is divided into multiple units by the grid-patterned configuration of conductive core 324 in the lateral plane, with each unit of the first dielectric layer 322 surrounding and isolating at least one transistor 130 within that plane. In some implementations, at least two transistors 130 are surrounded by each unit of first dielectric layer 322, as shown in semiconductor device 402 in FIG. 4B. In some implementations, the number of transistors 130 surrounded and isolated by each unit of first dielectric layer 322 varies. For example, a part unit of first dielectric layer 322 surrounds and isolates one transistor 130 while other units surround and isolate two, three, or four transistors 130. The number of the transistors 130 that are surrounded and isolated by each unit of first dielectric layer 322 is determined by the design and the structure of semiconductor device 402 and should not be read as a limit of the present disclosure. Furthermore, conductive core 324 includes multiple contacts 326 situated at its edge, facilitating a connection between conductive core 324 and a negative voltage or ground. The number and locations of contacts 326 can be arranged based on the area and shape of the semiconductor device 100 in consideration of its fabrication process. It should be noted that the shape of conductive core 324 is illustrative and should not be read as limits of the present disclosure. For example, conductive core 324 may be strips parallel to each other in other implementations.

It is understood that the relative positions and arrangement of transistors 130 are not limited to the examples shown above depending on the various fabrication processes as described below in detail. It is also understood that the details of the same structures or components (e.g., materials, fabrication process, functions, etc.) in both semiconductor devices 200, 300, 401, and 402 are not repeated for ease of description.

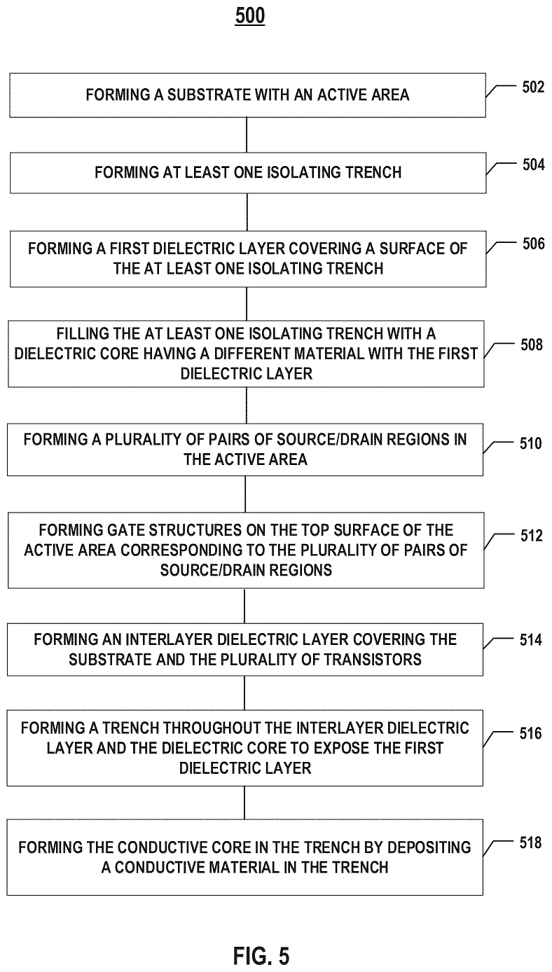

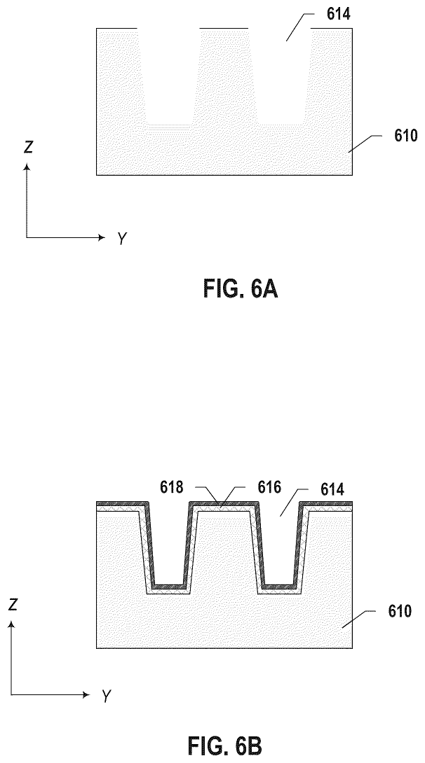

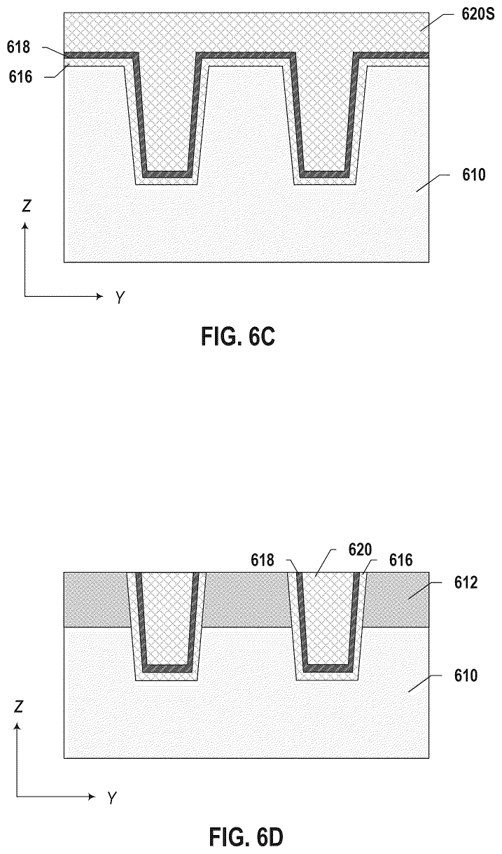

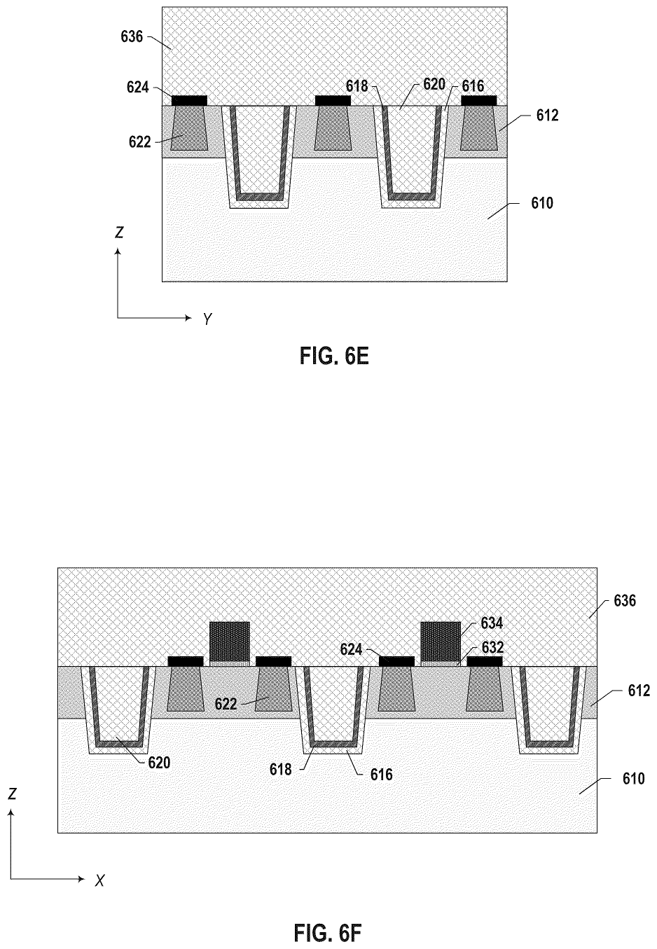

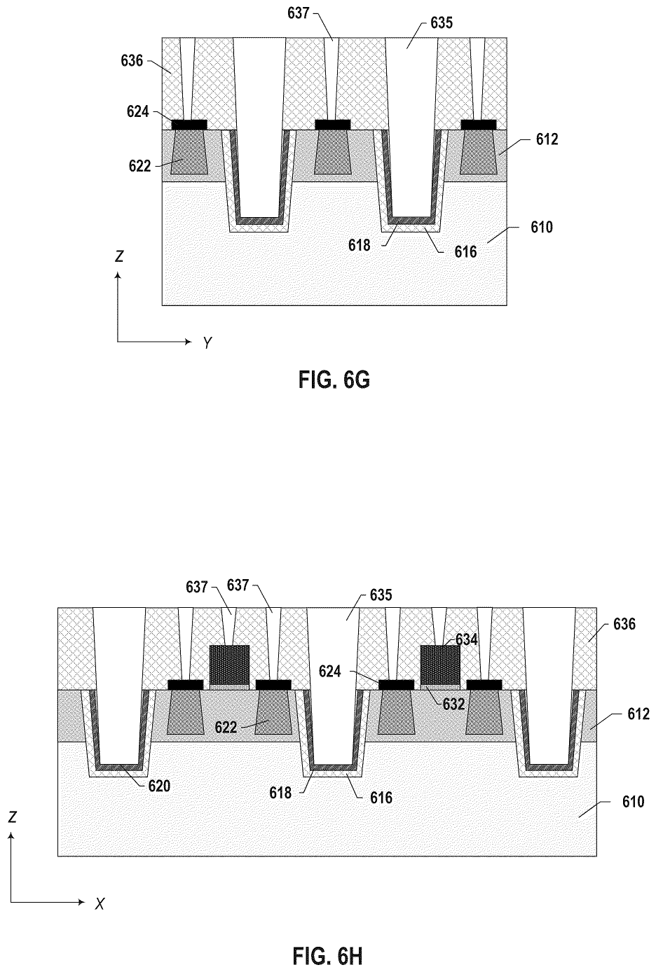

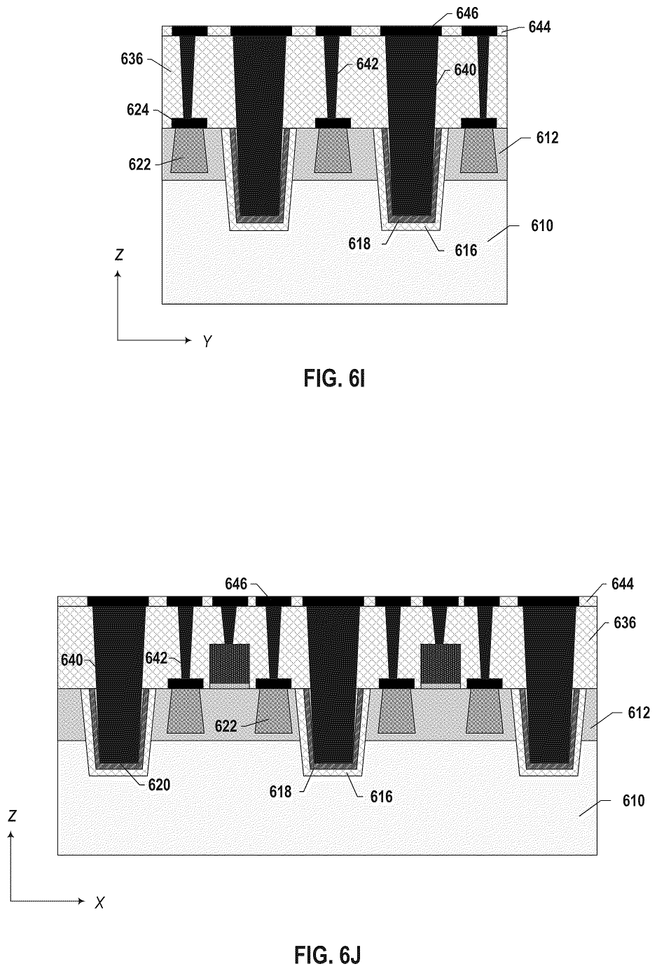

FIG. 5 illustrates a flowchart of a method 500 for forming a semiconductor device including transistors with conductive core, such as semiconductor devices 200 described above in connection with FIGS. 2A and 2B or semiconductor device 401 described above in connection with FIG. 4A, according to some implementations of the present disclosure. FIGS. 6A-6J illustrate a fabrication process for forming a semiconductor device at certain fabricating stages of the method 500 shown in FIG. 5, according to various implementations of the present disclosure. It is understood that the operations shown in method 500 are not exhaustive and that other operations can be performed as well before, after, or between any of the illustrated operations. Further, some of the operations may be performed simultaneously, or in a different order than shown in FIG. 5.

As shown in FIG. 5, method 500 can start at operation 502, in which a substrate 610 is provided. Substrate 610 can include silicon (e.g., single crystalline silicon, c-Si), silicon germanium (SiGe), gallium arsenide (GaAs), germanium (Ge), silicon-on-insulator (SOI), or any other suitable materials. Active area 612 can be formed before or after the formation of isolation trenches 614. Here, for instance, active area 612 is formed after forming isolation trenches 614. Then method 500 can proceed to operation 504, in which at least one isolating trench 614 is formed on substrate 610, as shown in FIG. 6A. FIG. 6A illustrates a schematic side cross-sectional view of the semiconductor device in y-z plane after operation 504 of method 500.

In some implementations, isolation trenches 614 can be formed by patterning processes, for example, photoetching, dry etching, wet etching, cleaning, chemical mechanical polishing (CMP), etc. In some implementations, the patterning process commences with the preparation of substrate 610. Substrate 610 undergoes a thorough cleaning to eliminate any contaminants that could hinder the formation of trenches. In some cases, additional surface treatments—such as oxide removal or chemical treatments—are applied to enhance the adhesion of subsequent layers. Following this preparation, a thin layer of silicon dioxide is deposited onto substrate 610 (not depicted in the figures). This silicon dioxide layer will function as a mask during the subsequent etching process. Next, a layer of photoresist is applied atop the silicon oxide layer using a spin-coating technique, ensuring uniform thickness across substrate 610. The photoresist is then exposed to ultraviolet (UV) light through a photomask that delineates the pattern for isolation trenches 614. Subsequently, the photoresist undergoes a developing process to remove either the exposed or unexposed regions, contingent upon whether a positive or negative photoresist is utilized, resulting in a patterned photoresist layer. An etching process is then employed to remove the underlying oxide layer in areas where the photoresist has been developed, thereby creating the intended pattern of isolation trenches 614 in the silicon oxide layer. The etching continues through substrate 610, employing a similar dry etching method. It is imperative that the parameters—such as pressure and gas composition—are meticulously controlled to achieve the anticipated trench depth and profile. Finally, the remaining photoresist is eliminated using an appropriate solvent or through plasma ashing, exposing the trench in the silicon substrate. The substrate is then cleaned to remove any residual materials resulting from the etching process.

As shown in FIG. 5, method 500 can proceed to operation 506, in which a first dielectric layer 618 covering a surface of the at least one isolating trench 614 is formed, as shown in FIG. 6B. FIG. 6B illustrates a schematic side cross-sectional view of the semiconductor device in z plane after operation 506 of method 500.

In some implementations, first dielectric layer 618 can be formed by thermal oxidation, oxide growth, chemical vapor deposition (CVD), atomic layer deposition (ALD), physical vapor deposition (PVD), or sputtering. In some implementations, a second dielectric layer 616 covering isolation trench 614 is formed before forming first dielectric layer 618, as shown in FIG. 6B. Second dielectric layer 616 is composed of a different material from the first dielectric layer 618, thereby allowing the second dielectric layer 616 to function effectively as an etching stop layer in various subsequent etching processes. This configuration ensures that the second dielectric layer 616 will not be removed and conductive core 640 will be adequately encased by at least second dielectric layer 616, preventing any contact with the active regions of adjacent transistors.

As shown in FIG. 5, method 500 can proceed to operation 508, in which the at least one isolating trench 614 is filled with a dielectric core 620 having a different material from first dielectric layer 618, as shown in FIGS. 6C and 6D. FIG. 6C illustrates a schematic side cross-sectional view of the semiconductor device in y-z plane after dielectric layer 620S is formed. FIG. 6D illustrates a schematic side cross-sectional view of the semiconductor device in y-z plane after active area 612 is formed.

In some implementations, a dielectric layer 620S can be formed on first dielectric layer 618 to fill isolation trenches 614 by thermal oxidation, oxide growth, CVD, ALD, PVD, or sputtering. As illustrated in FIG. 6C, dielectric layer 620S is not only formed within isolation trenches 614 but also formed to extend over the entirety of first dielectric layer 618. Subsequently, dielectric layer 620S outside isolation trenches 614 must be removed to expose the first dielectric layer 618 through the process of chemical mechanical planarization (CMP), as depicted in FIG. 6D. Dielectric core 620 can be consisted by the dielectric layer 620S remained in isolation trench 614.

In some implementations, active area 612 is formed thereafter as shown in FIG. 6D. For example, active area 612 can be formed by ion implantation or diffusion, dopants (such as phosphorus or boron) are introduced into substrate 610 to create n-type or p-type regions among the plurality of isolation trenches 614, respectively. In some implementations, a depth of the at least one isolating trench 614 is greater than a depth of active area 612, and a depth of the first dielectric layer 618 is greater than a depth of the active area 612.

As shown in FIG. 5, method 500 can proceed to operations 510 and 512, in which a plurality of gate structures are formed on substrate 610 and a plurality pairs of source and drain regions 622 corresponding to the gate structures are formed in active area 612, as shown in FIGS. 6E and 6F. FIG. 6E illustrates a schematic side cross-sectional view of the semiconductor device in y-z plane after operation 512 of method 500. FIG. 6F illustrates a schematic side cross-sectional view of the semiconductor device in x-z plane after operation 512 of method 500.

In some implementations, a gate dielectric 632 is first formed on substrate 610, covering a central portion of the active area 612. This can be achieved through methods such as thermal oxidation, oxide growth, chemical vapor deposition (CVD), atomic layer deposition (ALD), physical vapor deposition (PVD), or sputtering. Gate dielectric 632 may include various dielectric materials, including silicon oxide, silicon nitride, or high-k dielectrics. High-k dielectric materials can include, but are not limited to, aluminum oxide (Al₂O₃), hafnium oxide (HfO₂), tantalum oxide (Ta₂O5), zirconium oxide (ZrO₂), titanium oxide (TiO₂), or any combination of these materials. Subsequently, a gate electrode 634 is formed on the gate dielectric 632 by depositing a conductive material using techniques such as CVD, ALD, PVD, or sputtering. Gate electrode 634 includes conductive materials including, but not limited to W, Co, Cu, Al, TiN, TaN, polysilicon, silicide, or any combination thereof. In some implementations, gate electrode 634 includes multiple conductive layers, such as a W layer over a TiN layer. In one example, gate structure may be a “gate oxide/gate poly” gate in which gate dielectric 632 includes silicon oxide and gate electrode includes doped polysilicon.

In some implementations, a plurality of pairs of source and drain regions 622 are formed after the formation of the gate structure. For example, source and drain regions 622 can be formed by ion implantation or diffusion taking the gate structure as a hard mask. Dopants (such as phosphorus or boron) are introduced into substrate 610 to create n-type or p-type regions among the plurality of isolation trenches 614, respectively.

In some implementations, a pair of spacers (not shown in the figures) are formed on a left side and a right side of the gate structure by depositing and etching a thin layer of dielectric material (like silicon nitride). Spacers can be helpful in defining the source and drain regions more precisely. Then perform ion implantation to introduce dopants (n-type for n-channel MOSFETs, p-type for p-channel MOSFETs) into the regions adjacent to the gate structure to form source and drain regions 622 in active area 612. In some implementations, an activation annealing process is performed after ion implantation to activate the dopants.

In some implementations, a dummy gate structure can be used to form the gate structure and source and drain regions 622. In this way, a dummy gate is formed first and then removed after the formation of source and drain regions 622. Gate dielectric 632 and gate electrode 634 will be formed after the dummy gate is removed. The sequences of the formation of the gate structure and source and drain regions 622 described above are illustrative and should not be read as limits of the present disclosure.

In some implementations, as shown in FIGS. 6E and 6F, a source and drain contact 624 is formed on source and drain regions 622 to reduce the resistance of source and drain regions 622. Source and drain contact 624 can be made of doped amorphous silicon, doped polysilicon, doped single crystal silicon, or doped silicon germanium (Si_{X} Ge_{1-X}). In some implementations, source and drain contact 624 can be formed by depositing a silicide covering a top surface of source and drain region 622. In some implementations, a contact is formed on a top surface of gate electrode 634 to reduce the contact resistance between gate electrode 634 and interconnectors 642, especially in the situation that gate electrode 634 is made of polysilicon.

As shown in FIG. 5, method 500 can proceed to operations 514 and 516, in which an ILD layer 636 is formed to cover substrate 610 and the plurality of transistors, and then a trench 635 throughout the ILD layer 636 and dielectric core 620 to expose first dielectric layer 618, as shown in FIGS. 6G and 6H. FIG. 6G illustrates a schematic side cross-sectional view of the semiconductor device in y-z plane after operation 516 of method 500. FIG. 6H illustrates a schematic side cross-sectional view of the semiconductor device in x-z plane after operation 516 of method 500.

In some implementations, ILD layer 636 has a same material as first dielectric layer 618, so that trench 635 can be etched in the same etching process. In some implementations, a plurality of holes 637 throughout ILD layer 636 expose source and drain regions 622 and gate structures of the transistors. The plurality of holes 637 are formed in the same formation process as trench 635.

As shown in FIG. 5, method 500 can proceed to operations 518, in which a conductive core 640 is formed in trench 635 by depositing a conductive material in trench 635, as shown in FIGS. 6I and 6J. FIG. 6I illustrates a schematic side cross-sectional view of the semiconductor device in y-z plane after operation 518 of method 500. FIG. 6J illustrates a schematic side cross-sectional view of the semiconductor device in x-z plane after operation 518 of method 500.

In some implementations, conductive core 640 can be formed in trench 635 by depositing a conductive material using techniques such as CVD, ALD, PVD, or sputtering. Conductive core 640 includes conductive materials including, but not limited to W, Co, Cu, Al, TiN, TaN, polysilicon, silicide, or any combination thereof. In some implementations, conductive core 640 includes multiple conductive layers, such as a W layer over a TiN layer. In some implementations, a plurality of interconnectors 642 are formed in the plurality of holes 637 by depositing conductive material in the plurality of holes. The plurality of interconnectors 642 can be formed in the same formation process of conductive core 640 using the same conductive material.

In some implementations, method 500 further includes forming an interconnect layer coupled with the transistors through the plurality of interconnectors 642. The interconnect layer is formed on ILD layer 636 to transfer electrical signals. Conductive core 640 can be coupled to the negative voltage or the ground through the interconnect layer. The interconnect layer can include interconnect lines 646 and via contacts in ILD layer 644. The interconnectors in interconnect layer can include conductive materials including, but not limited to, W, Co, Cu, Al, doped silicon, silicide, or any combination thereof. The ILD layers can be formed with dielectric materials including, but not limited to, silicon oxide, silicon nitride, silicon oxynitride, low-k dielectrics, or any combination thereof.

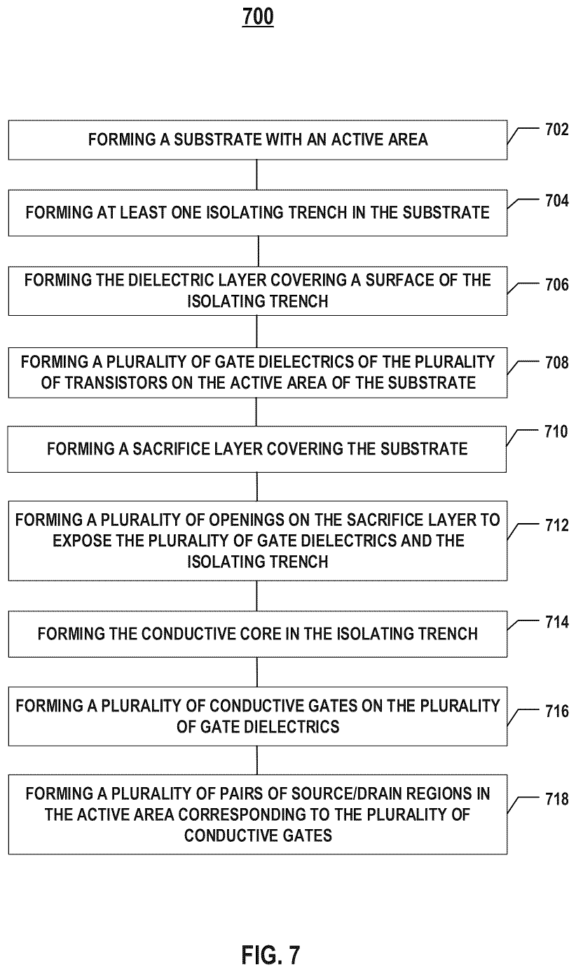

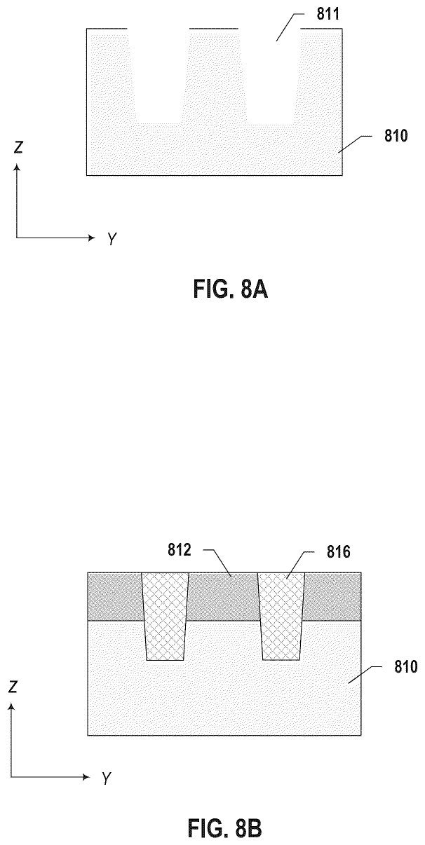

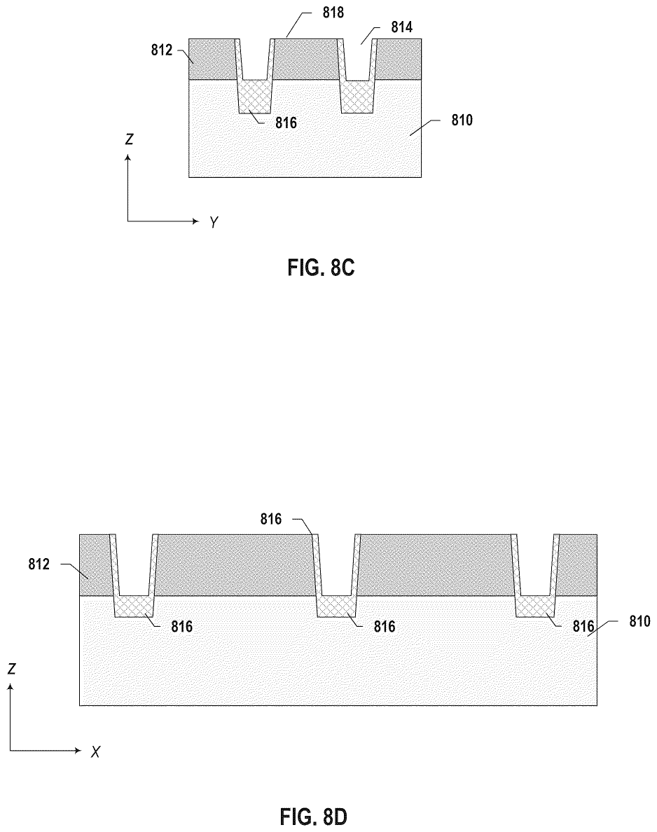

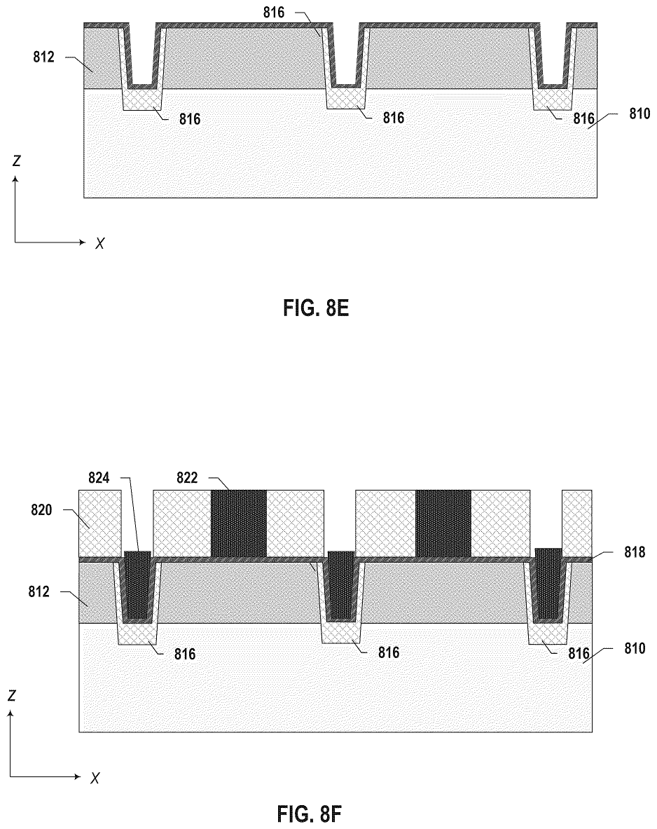

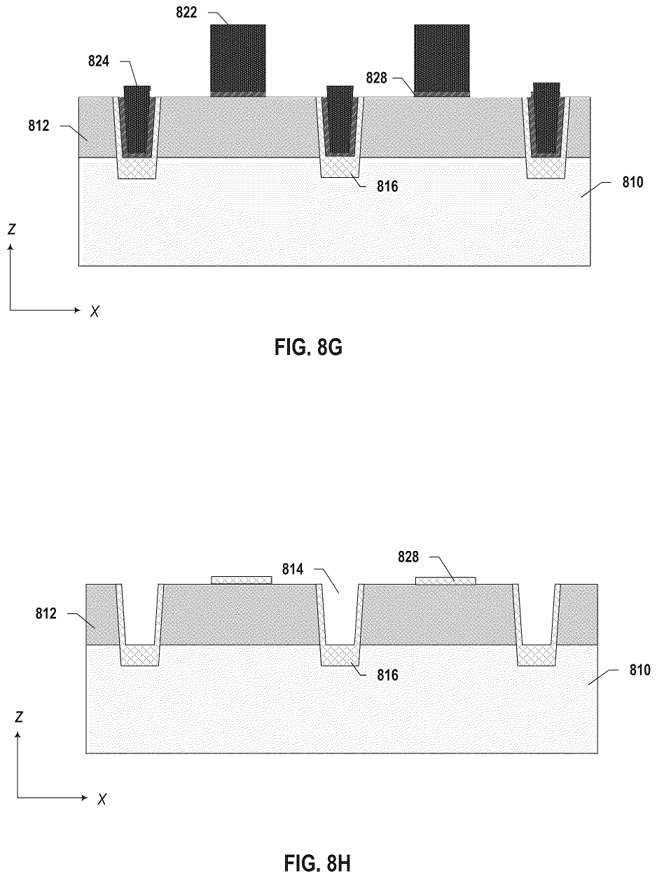

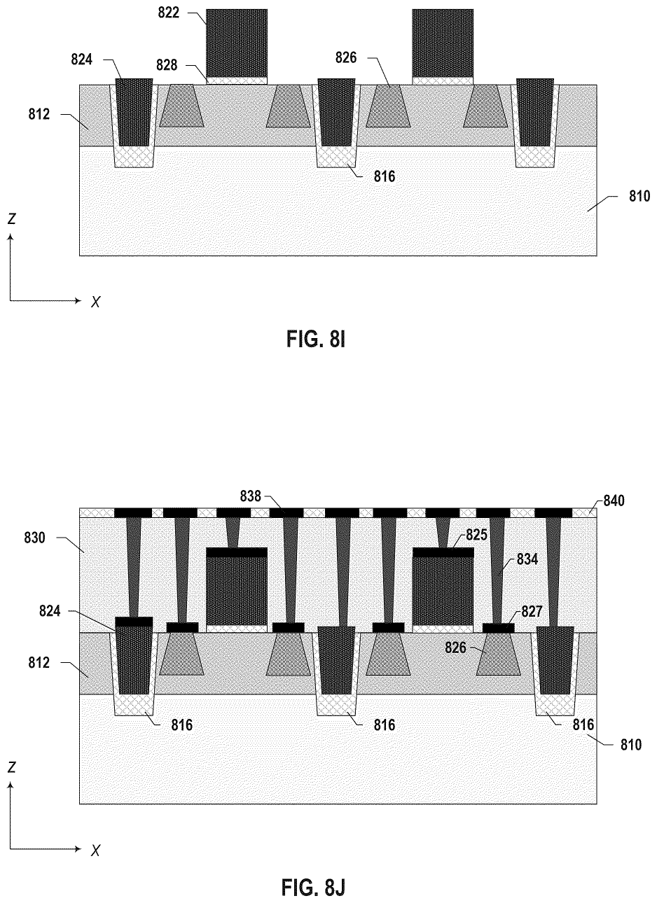

FIG. 7 illustrates a flowchart of a method 700 for forming a semiconductor device including transistors with conductive core, such as semiconductor devices 200 described above in connection with FIGS. 3A and 3B or semiconductor device 402 described above in connection with FIG. 4B, according to some implementations of the present disclosure. FIGS. 8A-8J illustrate a fabrication process for forming a semiconductor device at certain fabricating stages of the method 700 shown in FIG. 7, according to various implementations of the present disclosure. It is understood that the operations shown in method 700 are not exhaustive and that other operations can be performed as well before, after, or between any of the illustrated operations. Further, some of the operations may be performed simultaneously, or in a different order than shown in FIG. 5.

As shown in FIG. 7, method 700 can start at operation 702, in which a substrate 810 is provided. Substrate 810 can include silicon (e.g., single crystalline silicon, c-Si), silicon germanium (SiGe), gallium arsenide (GaAs), germanium (Ge), silicon-on-insulator (SOI), or any other suitable materials. Active area 812 can be formed before or after the formation of isolation trenches 814. Here, for instance, active area 812 is formed after forming isolation trenches 814. Then method 700 can proceed to operations 704 and 706, in which at least one isolating trench 814 is formed in substrate 810, as shown in FIGS. 8A-8D. FIG. 8A illustrates a schematic side cross-sectional view of the semiconductor device in y-z plane after a formation of an STI trench 811. FIG. 8B illustrates a schematic side cross-sectional view of the semiconductor device in y-z plane after a formation of an STI structure 816. FIG. 8C illustrates a schematic side cross-sectional view of the semiconductor device in y-z plane after a formation of isolation trenches 814. FIG. 8D illustrates a schematic side cross-sectional view of the semiconductor device in x-z plane after a formation of isolation trenches 814.

In some implementations, as shown in FIGS. 8A and 8B, STI structure 816 is formed on substrate 810. First, a layer of photoresist is applied on substrate 810, then photolithography is used to expose the photoresist to UV light through a hard mask that defines regions for STI trench 811. Then the photoresist is developed to create openings where STI trench 811 will be etched. Then a dry etching process (such as Reactive Ion Etching, RIE) is performed to etch STI trench 811 into substrate 810, as shown in FIG. 8A. The depth of STI trench 811 is typically in the range of a few hundred nanometers to a few micrometers, depending on the technology node. After etching, the remaining photoresist is removed using a suitable solvent or plasma ashing. Then a layer of silicon dioxide is deposited to fill STI trench 811. This can be done through Thermal Oxidation, CVD or ALD. Then a CMP process is performed to planarize the surface of substrate 810, ensuring that the silicon oxide is level with surrounding silicon surface. In some implementations, any excess oxide may be removed from the top surface of substrate 810, leaving the STI oxide only in the trenches, as shown in FIG. 8B.

In some implementations, active area 812 is formed after STI structure 816 is formed, as shown in FIG. 8B. For example, active area 812 can be formed by ion implantation or diffusion, dopants (such as phosphorus or boron) are introduced into substrate 810 to create n-type or p-type regions among the plurality of STI structures 816, respectively. In some implementations, a depth of the at least one STI structure 816 is greater than a depth of active area 812.

In some implementations, isolation trenches 814 can be formed in STI structure 816 as shown in FIGS. 8C and 8D. In some implementations, isolation trenches 814 can be formed in a pre-clean process for the fabrication of gate dielectric 828 using a same hard mask as the fabrication process of STI structure 816. A fabrication processes for isolation trenches 814 will not be detailed here to avoid redundancy. It should be understandable that an opening of isolation trenches 814 is formed within STI structure 816 and isolation trenches 814 is wholly surrounded by STI structure 816 to avoid conductive core 824 from contacting with active area 812. In some implementations, depth of isolation trenches 814 is greater than or equal to a depth of active area 812.

As shown in FIG. 7, method 700 can proceed to operation 708, in which a gate dielectric layer 818 of the plurality of transistors is formed on active area 812 of the substrate 810, as shown in FIG. 8E-. FIG. 8E illustrates a schematic side cross-sectional view of the semiconductor device in y-z plane after operation 708 of method 700.

In some implementations, gate dielectric layer 818 can be formed by thermal oxidation, oxide growth, chemical vapor deposition (CVD), atomic layer deposition (ALD), physical vapor deposition (PVD), or sputtering. In some implementations, gate dielectric layer 818 is composed of a different material from the dielectric layer 816. Gate dielectric layer 818 may include various dielectric materials, including silicon oxide, silicon nitride, or high-k dielectrics. High-k dielectric materials can include, but are not limited to, aluminum oxide (Al₂O₃), hafnium oxide (HfO₂), tantalum oxide (Ta₂O₇), zirconium oxide (ZrO₂), titanium oxide (TiO₂), or any combination of these materials.

As illustrated in FIG. 7, method 700 proceeds to operation 710, in which a sacrifice layer 820 is formed over gate dielectric layer 818. This is followed by operation 712, in which a series of first openings 819 and second openings 821 are created in the sacrifice layer 820, thereby exposing the gate dielectric layer 818, as depicted in FIG. 8F. FIG. 8F illustrates a schematic side cross-sectional view of the semiconductor device in x-z plane after operation 712 of method 700.

In implementations, sacrifice layer 820 can be formed on gate dielectric layer 818 to fill isolation trenches 814 by thermal oxidation, oxide growth, CVD, ALD, PVD, or sputtering. The plurality of first openings and the plurality of second openings are then formed in sacrifice layer 820 to expose gate dielectrics layer 818. First openings are formed aligning with isolation trenches 814 and are configured to expose gate dielectric layer 818. Second openings are formed to form gate electrode, which are located at the center portion of active area 812.

As illustrated in FIG. 7, method 700 proceeds to operation 714, in which a plurality of conductive cores 824 are formed in the first opening, and operation 716, in which a plurality of gate electrodes are formed in the second openings, as shown in FIG. 8F. In some implementations, operations 714 and 716 can be performed in the same fabrication process.

In some implementations, conductive materials can be formed in the first openings and the second openings by thermal oxidation, oxide growth, CVD, ALD, PVD, or sputtering. Referring to FIG. 8F, conductive cores 824 comprises conductive materials formed in the first openings, and gate electrodes 822 comprises conductive materials formed in the second openings. The conductive materials may include doped polysilicon, i.e., gate poly. In some implementations, conductive materials include multiple conductive layers, such as a W layer over a TiN layer. In some implementations, gate dielectrics layer 818 is patterned to form a gate dielectric 828 by using gate electrodes 822 as a hard mask.

Gate electrodes 822 and conductive cores 824 have the same height as they are formed in the same fabrication process. Sacrifice layer 820 can then be removed by wet etching as shown in FIG. 8G. FIG. 8G illustrates a schematic side cross-sectional view of the semiconductor device in x-z plane after sacrifice layer 820 is removed and gate dielectrics layer 818 is patterned. Operations 714 and 716 can be performed in the same fabrication process. The formation of conductive cores 824 does not cost any additional resources nor increase any fabrication complexity, like the formation of the first openings.

In some implementations, another fabrication flow may be employed to form the gate structure and the conductive core. FIG. 8H illustrates a schematic side cross-sectional view of the semiconductor device in x-z plane after gate dielectric 828 is formed according to some implementations of the present disclosure, in which gate dielectric 828 includes silicon oxide. Gate dielectric 828 can be formed by thermal oxidation, oxide growth, CVD, ALD, PVD, or sputtering using photolithography. In some implementations, gate dielectric 828 is formed only under gate electrode 822 and will not be formed in isolation trenches 814, as shown in FIG. 8H.

In some implementations, conductive materials can be formed on gate dielectric 828 to form gate electrode 822. Conductive cores 824 can be formed in isolation trenches 814 in the same fabrication process as gate electrode 822, as shown in FIG. 8I. The conductive materials may include doped polysilicon, i.e., gate poly. In some implementations, conductive materials include multiple conductive layers, such as a W layer over a TiN layer. Gate electrodes 822 and conductive cores 824 have the same height as they are formed in the same fabrication process. In some implementations, a top surface of conductive cores 824 is higher than the top surface of substrate 810, as shown in FIG. 8I.

As illustrated in FIG. 7, method 700 proceeds to operation 718, in which a plurality of pairs of source and drain regions 826 are formed in active area 812 corresponding to the plurality of conductive gates, as shown in FIG. 8I.

In some implementations, a plurality of pairs of source and drain regions 826 are formed after the formation of the gate structure. For example, source and drain regions 826 can be formed by ion implantation or diffusion taking the gate structure as a hard mask. Dopants (such as phosphorus or boron) are introduced into substrate 810 to create n-type or p-type regions among the plurality of conductive cores 824, respectively. In some implementations, a source and drain contact 827 is formed on source and drain regions 826 to reduce the resistance of source and drain regions 826. Source and drain contact 827 can be made of doped amorphous silicon, doped polysilicon, doped single crystal silicon, or doped silicon germanium (Si_{X} Ge_{1-X}). In some implementations, source and drain contact 827 can be formed by depositing a silicide covering a top surface of source and drain region 826. In some implementations, a contact 825 is formed on a top surface of gate electrode 822 to reduce the contact resistance between gate electrode 822 and interconnectors 834, especially in the situation that gate electrode 822 is made of polysilicon.

In some implementations, method 700 can further include forming an ILD layer 830 to cover substrate 810 and the plurality of transistors, as shown in FIG. 8H. FIG. 8H illustrates a schematic side cross-sectional view of the semiconductor device in x-z plane after the formation of ILD layer 830.

In some implementations, an ILD layer 830 is formed on substrate 810 to cover the transistors. In some implementations, a plurality of holes 832 throughout ILD layer 830 expose source and drain regions 826 and gate structures of the transistors. Depths of the plurality of holes 832 are different depending on the height and location to which hole 832 is connected. For example, the depth of hole 832 connected to source and drain region 826 is greater than the depth of hole 832 connected to gate electrode 822.

In some implementations, the plurality of holes 832 are filled with conductive materials by depositing a conductive material using techniques such as CVD, ALD, PVD, or sputtering. Conductive core 824 includes conductive materials including, but not limited to W, Co, Cu, Al, TiN, TaN, polysilicon, silicide, or any combination thereof.

In some implementations, method 700 further includes forming an interconnect layer coupled with the transistors through the plurality of connectors 834. The interconnect layer is formed on ILD layer 830 to transfer electrical signals. Conductive core 824 can be coupled to the negative voltage or the ground through the interconnect layer. The interconnect layer can include interconnect lines 838 ILD layer 840. The interconnectors in interconnect layer can include conductive materials including, but not limited to, W, Co, Cu, Al, doped silicon, silicide, or any combination thereof. The ILD layers can be formed with dielectric materials including, but not limited to, silicon oxide, silicon nitride, silicon oxynitride, low-k dielectrics, or any combination thereof.

The foregoing description of the specific implementations can be readily modified and/or adapted for various applications. Therefore, such adaptations and modifications are intended to be within the meaning and range of equivalents of the disclosed implementations, based on the teaching and guidance presented herein. The breadth and scope of the present disclosure should not be limited by any of the above-described exemplary implementations but should be defined only in accordance with the following claims and their equivalents.

What is claimed is:

1. A semiconductor device, comprising
a substrate;
an active area in the substrate;
a plurality of transistors in the active area; and
at least one isolation structure positioned between two adjacent transistors; wherein each isolation structure of the at least one isolation structure comprises:
a conductive core; and
a dielectric layer surrounding the conductive core and positioned between the conductive core and an adjacent transistor.

2. The semiconductor device of claim 1, wherein the conductive core has a grid pattern in a lateral plane, and the dielectric layer are split into a plurality of units by the conductive core in the lateral plane, each unit of the dielectric layer surrounds and isolates at least one transistor in the lateral plane.

3. The semiconductor device of claim 1, wherein along a vertical direction, a first distance between a bottom of the conductive core and a bottom of the substrate is smaller than a second distance between a bottom of the active area and the bottom of the substrate.

4. The semiconductor device of claim 3, wherein along the vertical direction, the conductive core comprises:
a first portion in the substrate; and
a second portion extended above the substrate and coupled to a conductive layer; wherein
the conductive core comprises a protrusion on a joint portion between the first portion and the second portion on a cross-section along the vertical direction.

5. The semiconductor device of claim 4, wherein a third distance between a bottom of the conductive core and a top of the active area ranges from 0.2 um to 0.8 um.

6. The semiconductor device of claim 5, wherein a fourth distance is a minimal distance between two adjacent transistors, and a ratio of the third distance to a fourth distance ranges from 1:1.7 to 1:0.127.

7. A method for fabricating a semiconductor device, comprising:
forming a substrate with an active area;
forming at least one isolation structure in the active area; and
forming a plurality of transistors isolated by the at least one isolation structure; wherein each isolation structure of the at least one isolation structure comprises:
a conductive core; and
a dielectric layer surrounding the conductive core and positioned between the conductive core and an adjacent transistor.

8. The method of claim 7, wherein forming the at least one isolation structure comprises:
forming at least one isolating trench;
forming a first dielectric layer covering a surface of the at least one isolating trench; and
filling the at least one isolating trench with a dielectric core having a different material from the first dielectric layer.

9. The method of claim 8, wherein a depth of the at least one isolating trench is greater than a depth of the active area.

10. The method of claim 9, wherein a depth of the first dielectric layer is greater than a depth of the active area.

11. The method of claim 8, wherein forming the plurality of transistors isolated by the at least one isolation structure comprises:
forming a plurality of pairs of source/drain regions in the active area; and
forming gate structures on a top surface of the active area corresponding to the plurality of pairs of source/drain regions.

12. The method of claim 11, further comprising:
forming an interlayer dielectric layer covering the substrate and the plurality of transistors; wherein
the interlayer dielectric layer and the first dielectric layer have a same material.

13. The method of claim 12, wherein forming the isolation structure further comprises:
forming a trench throughout the interlayer dielectric layer and the dielectric core to expose the first dielectric layer; and
forming a second dielectric layer covering the isolation trench before forming the first dielectric layer, and the second dielectric layer and the first dielectric layer have different materials.

14. The method of claim 13, further comprising:
forming a plurality of holes throughout the interlayer dielectric layer to expose source/drain regions and gate structures of the transistors; wherein
the plurality of holes are formed in a same formation process as the trench.

15. The method of claim 14, wherein forming the isolation structure further comprises:
forming the conductive core in the trench by depositing a conductive material in the trench;
forming a plurality of interconnectors in the plurality of holes by depositing the conductive material in the plurality of holes; wherein
the plurality of interconnectors are formed in a same formation process as the conductive core.

16. A method for fabricating a semiconductor device, comprising:
forming a substrate with an active area; and
forming at least one isolation structure in the active area and a plurality of transistors isolated by the at least one isolation structure; wherein
each isolation structure of the at least one isolation structure comprises:
a conductive core; and
a dielectric layer surrounding the conductive core and positioned between the conductive core and an adjacent transistor; wherein
gates of the plurality of transistors and the conductive core have a same material.

17. The method of claim 16, wherein forming at least one isolation structure in the active area and the plurality of transistors comprises:
forming at least one isolating trench in the substrate;
forming the dielectric layer covering a surface of the isolating trench; and
forming a plurality of gate dielectrics of the plurality of transistors on the active area of the substrate.

18. The method of claim 17, wherein forming at least one isolation structure in the active area and the plurality of transistors comprises:
forming a sacrifice layer covering the substrate, wherein a material of the sacrifice layer is different from the substrate; and
forming a plurality of openings on the sacrifice layer to expose the plurality of gate dielectrics and the isolating trench.

19. The method of claim 18, wherein forming at least one isolation structure in the active area and the plurality of transistors comprises:
forming the conductive core in the isolating trench;
forming a plurality of conductive gates on the plurality of gate dielectrics; and
forming a plurality of pairs of source/drain regions in the active area corresponding to the plurality of conductive gates; wherein
the conductive core and the conductive gates are formed in a same formation process by depositing conductive materials via the plurality of openings.

20. The method of claim 19, wherein forming at least one isolation structure in the active area and the plurality of transistors comprises:
forming an interlayer dielectric layer covering the substrate and the transistors;
forming a plurality of holes throughout the interlayer dielectric layer to expose the conductive core, the source/drain regions, and gate structures; and
forming a plurality of interconnectors in the plurality of holes.
